(19) United States
(12) Patent Application Publication
(10) Pub. No.: US 2026/0354060 A1
(43) Pub. Date: Nov. 5, 2026

(54) Fabrication of Semiconductor Materials Using Spin-On Dopants

(71) Applicant: Northeastern University, Boston, MA (US)

(72) Inventors: Ahmed BUSNAINA, Needham, MA (US); Ahmed Mostafa Hafez Abdelaziz, College Park, MD (US)

(21) Appl. No.: 19/666,028

(22) Filed: May 1, 2026

Related U.S. Application Data
(60) Provisional application No. 63/798,078, filed on May 1, 2025.

(51) Int. Cl. H10P 32/14; H10D 30/60

(52) U.S. Cl. CPC H10P 32/1408; H10D 30/60

(57) ABSTRACT

Methods of patterned doping of semiconductor materials using spin-on dopants exploit fast fluidic assembly on semiconductor surfaces. Selective dopant deposition is achieved using a patterned hydrophobic self-assembled monolayer followed by depositing a spin-on dopant in the intervening hydrophilic spaces. Rapid thermal annealing (RTA) is then performed to drive the thermal diffusion of dopant atoms into the substrate to a targeted depth. The method is applicable to a variety of p-type and n-type dopants and supports a fully additive fabrication flow for fabrication of active components such as field-effect transistors without requiring high-vacuum etching, ion implantation, or conventional oxide growth.

### CROSS REFERENCE TO RELATED APPLICATIONS

This application claims the priority of U.S. Provisional Application No. 63/798,078 filed 1 May 2025 and entitled “Fabrication of Semiconductor Materials Using Spin-On Dopants”, the whole of which is hereby incorporated by reference.

### BACKGROUND

Silicon-based integrated circuit miniaturization presents fundamental challenges in modern semiconductor technology. One of the major challenges is attaining controlled doping of semiconductor materials with micro-and nano-scale accuracy. The formation of nanoscale junctions for electronic devices depends critically on the impurities introduced into substrates, which must be carefully managed to modify electrical properties in a controlled manner. Conventional fabrication techniques such as ion implantation and solid-source diffusion have been widely employed to achieve accurate large-scale doping. However, these methods encounter significant limitations when applied to nanoscale structures. Ion implantation, for example, relies on high-energy ion beams bombarding the substrate to attain the required doping profile. Although effective at larger scales, this technique is destructive and can damage the crystalline lattice of the bombarded materials, making it unsuitable for nanostructured devices including nanopillars, nanowires, and nanotubes. Furthermore, post-implantation processes typically necessitate high-temperature annealing to repair ion-beam-induced defects. On the other hand, solid-source diffusion offers excellent control over dopant profiles and concentrations, but it lacks doping uniformity and selectivity, typically introducing dopants across the entire substrate. To address these limitations, there is a need to develop processes that enable precise control over dopant incorporation and the achievement of higher doping concentrations.

### SUMMARY

The present technology relates to a method for doping of a substrate for fabricating semiconductor materials, and more particularly to a method for selectively doping semiconductor substrates using solution-based dopant deposition guided by chemically engineered surface patterns.

The present technology provides a novel and reliable approach to controlled doping of miniaturized electronic devices. By exploiting fast fluidic assembly on chemically engineered silicon surfaces, the fabrication of metal-oxide-semiconductor field-effect transistors (MOSFETs) with significant on-off ratios and notable carrier mobilities is achieved. The fast fluidic assembly doping strategy of the present technology consists of two key steps. First, selective dopant deposition is achieved by modifying the substrate's surface chemistry to enable dopant adsorption from solution-based suspensions. Second, rapid thermal annealing (RTA) is performed to drive the thermal diffusion of dopant atoms into the substrate to a targeted depth. This straightforward method is applicable to a variety of p-type and n-type dopants, and it supports a fully additive fabrication flow for field-effect transistors without requiring high-vacuum etching or conventional oxide growth. As a result, an areal dopant dose can be precisely controlled in both depth and lateral extent, enabling improved performance and scalability in miniaturized electronic devices.

The present technology can be further summarized by the following list of features.
1. A method of patterned doping of a substrate, the method comprising:
   (a) providing a semiconductor substrate having a hydrophilic surface;
   (b) applying a patterned photoresist coating to the substrate surface using lithography, thereby covering one or more selected doping regions and exposing one or more non-doping regions on the surface;
   (c) forming a hydrophobic self-assembled monolayer on the one or more exposed non-doping regions thereby rendering them hydrophobic;
   (d) removing the patterned photoresist coating while leaving the self-assembled monolayer on the one or more non-doping regions, thereby exposing the substrate surface in the one or more selected doping regions;
   (e) depositing a spin-on-dopant on the exposed substrate surface in the one or more doping regions using fluidic assembly, whereby the spin-on dopant composition selectively wets and coats the one or more selected doping regions and de-wets from the one or more non-doping regions;
   (f) depositing a spin-on-glass encapsulation layer over the entire surface of the semiconductor substrate resulting from step (e), whereby the one or more doping regions and the one or more non-doping regions are covered by the encapsulation layer;
   (g) thermally diffusing dopant atoms from the spin-on-dopant composition into the semiconductor substrate selectively in the one or more intended doping regions while the spin-on-glass encapsulation layer confines the spin-on-dopant composition to the one or more doping regions; and
   (h) removing the spin-on-glass encapsulation layer and residual spin-on-dopant from the semiconductor substrate.
2. The method of feature 1, further comprising, prior to B, treating the substrate with an oxygen plasma, whereby a surface of the substrate becomes hydrophilic.
3. The method of feature 1 or feature 2, wherein step C comprises exposing the substrate surface to perfluorooctyltrichlorosilane (FOTS) vapor, or another fluorinated organosilane to form the self-assembled monolayer.
4. The method of feature 3, wherein the self-assembled monolayer has a thickness of about 3 nanometers and a contact angle of about 110 degrees.
5. The method of any of the preceding features, wherein the depositing in step E comprises dip coating, fast fluidic assembly, or directed fluidic assembly by immersing the semiconductor substrate in a spin-on-dopant solution and withdrawing the substrate through a surface of the solution.
6. The method of feature 5, wherein the semiconductor substrate is withdrawn at a speed from about 10 mm/min to about 100 mm/min, preferably about 40 mm/min.
7. The method of any of the preceding features, further comprising, after selectively depositing the spin-on-dopant composition, heating the spin-on-dopant composition at a temperature from about 100 °C to about 200 °C for a time sufficient to remove at least a portion of solvent from the spin-on-dopant composition before depositing the spin-on-glass encapsulation layer.
8. The method of any of the preceding features, further comprising heating the spin-on-glass encapsulation layer at a temperature from about 150 °C to about 250 °C for a time sufficient to remove at least a portion of solvent from the spin-on-glass encapsulation layer before thermally diffusing the dopant atoms.
9. The method of any of the preceding features, wherein thermally diffusing the dopant atoms comprises rapid thermal annealing at a temperature from about 850 °C to about 1050 °C for a duration from about 30 seconds to about 2 minutes under an inert atmosphere.
10. The method of any of the preceding features, wherein step H comprises wet etching the spin-on-glass encapsulation layer and residual spin-on-dopant composition with an aqueous hydrofluoric acid solution.
11. The method of any of the preceding features, wherein the spin-on-dopant comprises a source of n-type dopant or a source of p-type dopant.
12. The method of any of the preceding features, wherein the spin-on-dopant comprises phosphorus atoms or boron atoms, or a compound comprising phosphorus or boron.
13. The method of any of the preceding features, wherein the semiconductor substrate comprises a semiconductor material having a first conductivity type, and wherein the spin-on-dopant composition provides dopant atoms of a second, opposite conductivity type in the one or more selected doping regions, such that an interface between a doped region and an adjacent non-doped or differently doped region forms a p-n junction after the thermal diffusion step.
14. The method of any of the preceding features, wherein the semiconductor substrate comprises or consists of silicon, silicon carbide, germanium, gallium nitride, gallium arsenide, or any combination thereof.
15. The method of any of the preceding features, further comprising, after removing the spin-on-glass encapsulation layer and residual spin-on-dopant composition on the surface, depositing one or more patterned structures onto the pattern doped substrate resulting from step H.
16. The method of feature 15, wherein the one or more patterned structures are one or more of a source contact, a drain contact, a gate dielectric, a gate electrode, an insulating layer, a metal contact, or an interconnect.
17. The method of any of feature 15, wherein the one or more device structures and the one or more doped regions form one or more metal oxide semiconductor field effect transistors (MOSFETs).
18. The method of feature 17, wherein the one or more MOSFETs are enhancement-mode MOSFETs in which source and drain doped regions are laterally separated by a channel region that is not bridged by dopant atoms after the thermal diffusion step.
19. The method of any of the preceding features, wherein the method does not include use of ion implantation, high vacuum dopant deposition, or dry etching.
20. The method of any of the preceding features, wherein the one or more doping regions have a lateral dimension in a range from about 1 micrometer to about 1 centimeter.
21. The method of any of the preceding features, wherein thermally diffusing the dopant atoms produces a vertical dopant diffusion depth of about 100 nm to about 1 micrometer and a lateral dopant diffusion length that does not bridge adjacent source and drain regions.
22. A semiconductor device comprising a semiconductor substrate, one or more doped regions selectively formed in the semiconductor substrate by thermal diffusion of dopant atoms from a spin-on-dopant composition, and one or more device structures electrically coupled to the one or more doped regions.
23. The semiconductor device of feature 22 which is a MOSFET having an on/off current ratio of at least 10000.
24. The semiconductor device of feature 23, wherein the MOSFET has an effective mobility of at least about 250 cm²/V·s, or about 300 cm²/V·s to about 320 cm²/V·s.

### BRIEF DESCRIPTION OF THE DRAWINGS

FIG. 1 schematically shows a method of substrate preparation for the fabrication process of an embodiment of semiconductor materials using spin-on dopants. Part (i) illustrates patterning the substrate with photoresist to create one or more non-doping regions and one or more doping regions, part (ii) illustrates treating the substrate to create a highly hydrophilic surface at the non-doping regions, part (iii) illustrates the self-assembled monolayer process rendering the non-doping regions hydrophobic while the doping regions covered by photoresist remain hydrophilic, part (iv) illustrates the substrate post dopant deposition with the doping regions coated with dopant and the non-doping regions not coated with dopant, part (v) illustrates the deposition of a spin-on-glass encapsulation layer over the entire surface of the substrate, part (vi) illustrates the heating process whereby the dopant atoms diffuse into the substrate at the doping regions, part (vii) illustrates removing the spin-on-glass encapsulation layer and residual spin-on-dopant from the substrate and patterning the substrate, and part (viii) illustrates depositing one or more patterned structures onto the substrate to create a device, such as a metal oxide semiconductor field effect transistor (MOSFET).

FIG. 2 illustrates immersing the substrate resulting from part (iii) of FIG. 1, after removal of the photoresist, in a spin-on-dopant solution and withdrawing the substrate so that the one or more doping regions are selectively coated with the spin-on-dopant.

FIG. 3 shows large-scale printing of approximately 35,000 transistors on a 4-inch wafer.

FIG. 4A shows an optical image of the substrate corresponding to the substrate shown in part (iv) of FIG. 1.

FIG. 4B schematically shows the final fabrication step corresponding to the semiconductor embodiment shown in part (viii) of FIG. 1.

FIG. 5A illustrates an embodiment of a depletion MOSFET formed using the method disclosed herein, the depletion MOSFET having a permanent fabricated channel formed between the source and drain.

FIG. 5B illustrates an embodiment of an enhancement MOSFET formed using the method disclosed herein, the enhancement MOSFET not having a channel formed between the source and drain, wherein the channel is created when voltage is applied at the gate.

FIGS. 6A-6D show time-of-flight secondary ion mass spectroscopy (TOF-SIMS) measurements for the phosphorus distribution inside the silicon substrate. FIG. 6A shows the measured region after depositing gold contacts. FIG. 6B shows normalized phosphorus ion concentration. FIG. 6C shows the phosphorus planar distribution. FIG. 6D shows the in-depth phosphorus distribution.

FIGS. 7A-7B show MOSFET current-voltage (I-V) measurements. FIG. 7A shows the current-voltage characteristics of devices with a channel length of 10 μm and a channel width of 100 μm. FIG. 7B shows the transfer characteristic curves at Vd=0.5 V for channel lengths of 10, 15, 20, 25, and 30 μm.

FIGS. 8A-8D show the fabrication steps of MOSFETs as simulated using the “Athena” module of the Silvaco CAD software package. FIG. 8A shows the boron and phosphorus doping profiles across the silicon substrate. FIG. 8B shows oxide and polysilicon mask layer deposition over the designated gate region. FIG. 8C shows phosphorus ion implantation and diffusion inside the silicon substrate. FIG. 8D shows the structure after etching of the polysilicon masking layer.

FIGS. 9A-9C show the MOSFET structure model. FIG. 9A shows the structure after aluminum contact deposition. FIG. 9B shows the final MOSFET structure after mirroring. FIG. 9C shows the current-voltage (I-V) characteristic curve for the designed MOSFET using the “Atlas” module of the Silvaco CAD software package.

FIGS. 10A-10B show MOSFET simulation results at an annealing time of approximately 4 minutes at 950 °C. FIG. 10A shows the phosphorus ion distribution inside the silicon substrate. FIG. 10B shows the I-V characteristics of the device, confirming enhancement-mode operation with negligible drain current at zero gate voltage.

FIGS. 11A-11B show MOSFET simulation results at an annealing time of approximately 6 minutes at 950 °C. FIG. 11A shows the phosphorus ion distribution inside the silicon substrate. FIG. 11B shows the I-V characteristics of the device, showing a small drain current flow at zero gate voltage due to reduced channel length.

FIGS. 12A-12B show MOSFET simulation results at an annealing time of approximately 8 minutes at 950 °C. FIG. 12A shows the phosphorus ion distribution inside the silicon substrate, showing a permanent n-channel formed under the gate. FIG. 12B shows the I-V characteristics of the device, exhibiting depletion-mode MOSFET behavior with large drain current flow at zero gate voltage.

### DETAILED DESCRIPTION

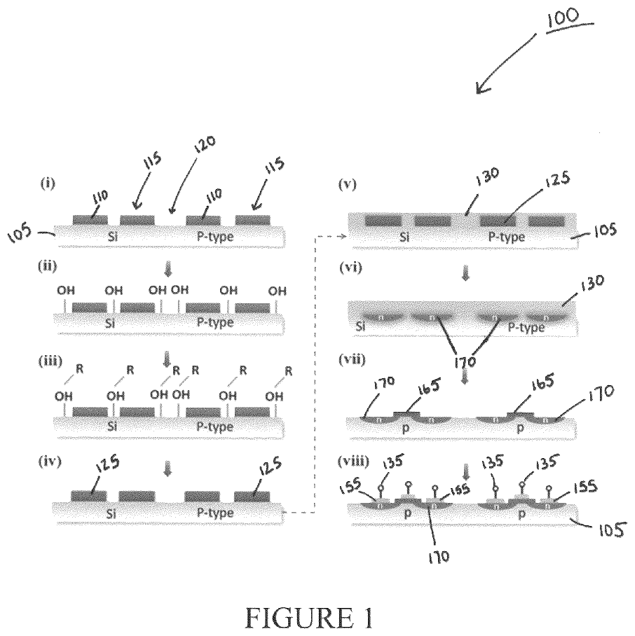

FIG. 1 schematically illustrates the fabrication process of a single crystal silicon MOSFET transistor in accordance with the present technology. The method begins by providing a substrate 105 of a first conductivity type that may have a hydrophilic surface. In an embodiment, the substrate 105 may be a boron-doped p-type silicon (Si) wafer that may have a (100) crystal orientation and a resistivity in the range of about 1 to about 10 ohm·cm. Prior to processing, the substrate 105 may be cleaned sequentially with acetone, deionized (DI) water, and isopropanol (IPA), and then dried under a nitrogen stream. It will be appreciated by those of ordinary skill in the art that the substrate 105 is not limited to p-type silicon; the present method is applicable to substrates of either p-type or n-type conductivity, and the substrate 105 may comprise or consist of silicon, silicon carbide, germanium, gallium nitride, gallium arsenide, or any combination thereof, or other materials suitable for doping via solution-based techniques. The selection of the conductivity type of the substrate 105 will depend on the desired device characteristics and the conductivity type of the dopant to be introduced, as discussed further below.

Following substrate 105 preparation, lithography may be used to pattern the semiconductor substrate 105 and define one or more device regions thereon, as depicted in FIG. 1 (part i). In an embodiment, photolithography (also referred to herein as optical lithography, or lithography in general) may be employed to define regions for source structures 140 and drain structures 145 for a MOSFET. A photoresist 110 may be applied to the substrate 105, exposed through a mask bearing the desired pattern, and developed to selectively remove the photoresist 110 from the non-doping regions 120 while the doping regions 115, including the designated locations for source structures 140 and drain structures 145 remain protected by the photoresist 110. The one or more doping regions 115 may have a lateral dimension in a range from about one micrometer to about one centimeter. Although photolithography is described in an embodiment, the technology is not so limited, and any suitable lithographic technique, including but not limited to electron-beam lithography and nanoimprint lithography, may be employed to define the doping and non-doping regions 120 with the requisite micro-or nano-scale accuracy.

The substrate 105 may be treated with a plasma to remove any organics and create a highly hydrophilic substrate 105 surface. In one embodiment, the plasma may be performed prior to the lithographic patterning, thereby rendering the entire substrate 105 surface hydrophilic before the photoresist 110 is applied. In another embodiment, the plasma treatment may be performed after lithographic patterning to render the exposed, non-doping region 120 surfaces of the substrate 105 hydrophilic, as depicted in FIG. 1 (part ii). In an embodiment, an oxygen (O₂) plasma treatment is conducted. This plasma treatment may serve a dual purpose: removing organic residues from the substrate 105 surface and simultaneously generating a highly hydrophilic surface by promoting the formation of hydroxyl groups on the substrate 105 surface. The resulting hydrophilic character, exhibiting a water contact angle of approximately 0°, is critical to enabling the selective dopant deposition that follows. While oxygen plasma is used in one embodiment, other plasma chemistries known to produce hydrophilic substrate 105 surfaces may be used without departing from the scope of the technology.

Following plasma treatment, the substrate 105 may be exposed to an organosilane vapor to form a self-assembled monolayer (SAM) on the non-doping regions 120 of the substrate 105, thereby rendering the non-doping regions 120 hydrophobic, as depicted in FIG. 1 (part iii). In an embodiment, the substrate 105 may be exposed to 2H-perfluorododecyltrichlorosilane (referred to herein as “PETS”) vapor at a temperature of approximately 95 °C for approximately 3 minutes. In another embodiment, the substrate 105 may be exposed to perfluorooctyltrichlorosilane (referred to herein as “FOTS”) vapor, or another fluorinated organosilane, to form the self-assembled monolayer. During this step, the organosilane molecules covalently bond to the hydroxyl groups present on the bare silicon regions, forming a SAM approximately 3 nm in thickness. The self-assembled monolayer may have a thickness of about 3 nm or may provide a water contact angle of about 90° to about 120°. This silanization process is a well-established technique for lowering the surface energy of substrates and imparting a hydrophobic character to the treated surface, resulting in a water contact angle of approximately 110° in an embodiment. Importantly, the doping regions 115 remain protected by photoresist 110 during the silanization step and thus do not receive the hydrophobic SAM coating.

After the organosilane exposure, the photoresist 110 mask may be stripped without removing the self-assembled monolayer, thereby exposing the substrate 105 surface at the one or more doping regions 115 and leaving behind a chemically heterogeneous semiconductor substrate 105. The resulting surface may comprise hydrophilic doping regions 115 (e.g., source and drain regions) surrounded by a hydrophobic background, or non-doping regions 120. This chemical contrast between the hydrophilic doping regions 115 and the hydrophobic non-doping regions 120 is central to the present technology, as it enables the highly selective, self-guided deposition of dopant material in the subsequent step.

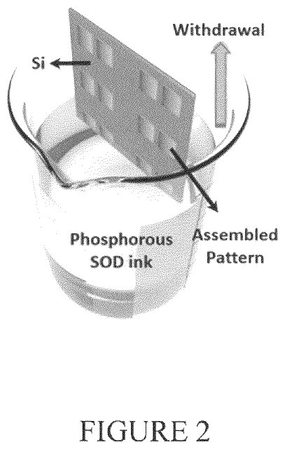

The chemically heterogeneous substrate 105 may then be subjected to a liquid-phase coating process, such as fast fluidic assembly (FFA), also referred to herein as dip coating or directed fast fluidic assembly, to selectively deposit a spin-on-dopant composition on the hydrophilic doping regions 115. In this step, the substrate 105 may be immersed in a solution comprising a spin-on-dopant 125 (SOD) of a second conductivity type opposite the first conductivity type of the substrate 105 and withdrawn through a surface of the solution. In one embodiment, the SOD 125 may be a phosphorus-containing ink (commercially available as PDC5-2500), and the substrate 105 may be a p-type silicon wafer, such that the phosphorus dopant will form n-type doped regions 170 upon diffusion. As shown in FIG. 2, the substrate 105 may be withdrawn through a surface of the SOD 125 solution at a controlled withdrawal speed, whereby the spin-on-dopant 125 composition selectively wets and coats the one or more selected doping regions 115 and dewets from the one or more non-doping regions 120. In an embodiment, the withdrawal speed may be approximately 40 mm/min. The withdrawal speed may range from about 10 mm/min to about 100 mm/min. Because of the chemically heterogeneous nature of the substrate 105 surface, the SOD 125 ink preferentially assembles on the hydrophilic doping regions 115, which have a high surface energy (water contact angle ~0°), while the ink de-wets from the hydrophobic non-doping regions 120, which have a substantially lower surface energy (water contact angle ~110°). This surface-energy-driven selective assembly enables dopant placement with high spatial accuracy without the need for additional patterning or masking steps, and without employing destructive techniques such as ion implantation. FIG. 1 (part iv) shows a schematic of the printed SOD 125 phosphorus film at the doping regions 115.

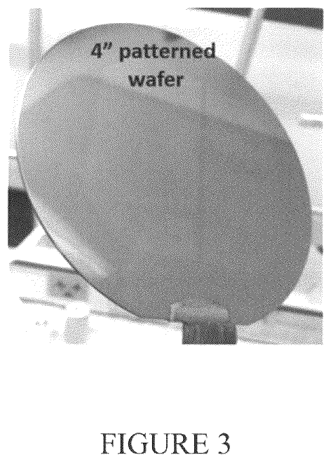

It should be appreciated that the fast fluidic assembly process is applicable to a wide range of dopants, including both p-type and n-type dopant species, and is not limited to phosphorus-based SOD 125 inks. For example, the spin-on-dopant 125 may comprise a source of n-type dopant or a p-type dopant, such as phosphorus atoms or boron atoms, or a compound comprising phosphorus or boron. The process has been demonstrated at wafer scale, with successful printing of SOD 125 on approximately 35,000 MOSFET source structures 140 and drain structures 145 on a 4-inch wafer in approximately one minute, as shown in FIG. 3, confirming the reliability and scalability of the technique for mass production.

Following dopant assembly, the substrate 105 may be subjected to a soft bake at a temperature from about 100 °C to about 200 °C, for example approximately 150 °C, for approximately 5 minutes, or for a time sufficient to remove at least a portion of solvent from the deposited spin-on-dopant 125 composition, before depositing a spin-on-glass 130 encapsulation layer.

After selective dopant deposition, a spin-on-glass 130 (SOG) encapsulation layer may be deposited over the entire surface of the substrate 105, including over the selectively assembled spin-on-dopant 125, as depicted in FIG. 1 (part v). The spin-on-glass 130 encapsulation layer may have a thickness from about 200 nm up to about 1000 nm. In an embodiment, a SOG 130 layer having a thickness of approximately 300 nm (commercially available as IC1-1000) may be deposited via spin coating. The SOG 130 encapsulation layer may be followed by heating at a temperature from about 150 °C to about 250 °C, for example approximately 200 °C, for approximately 10 minutes, or for a time sufficient to remove at least a portion of solvent from the spin-on-glass 130 encapsulation layer, before thermally diffusing the dopant atoms.

The SOG 130 encapsulation layer may serve three critical functions during the subsequent thermal diffusion step. First, the SOG 130 layer may confine the spin-on-dopant 125 composition to the one or more intended doping regions 115 during diffusion, which is essential to achieving well-defined doping profiles with precise lateral extent. Second, the SOG 130 layer may suppress the loss of dopant atoms to the ambient atmosphere, instead directing the diffusion of dopant atoms toward the substrate 105. Third, the SOG 130 layer may reduce dopant redeposition on the one or more non-doping regions 120, which could otherwise compromise device performance. This encapsulation step results in well-confined regions with highly concentrated doping profiles.

Following encapsulation, rapid thermal annealing (RTA) may be performed to thermally diffuse dopant atoms from the spin-on-dopant 125 composition into the semiconductor substrate 105 selectively in the one or more intended doping regions 115, while the spin-on-glass 130 encapsulation layer may confine the spin-on-dopant 125 composition and may reduce undesired dopant redeposition or diffusion in the one or more non-doping regions 120. In an embodiment, the RTA may be performed at a temperature from about 850 °C to about 1050 °C for a duration from about 30 seconds to about 2 minutes under an inert atmosphere. In a specific embodiment, the RTA may be performed at a temperature of approximately 950 °C. Where the semiconductor substrate 105 comprises a semiconductor material of a first conductivity type and the spin-on-dopant 125 composition provides dopant atoms of a second, opposite conductivity type in the one or more intended doping regions 115, the interface between a doped region 170 and an adjacent non-doped region 170 or differently doped region of the substrate 105 may form a p-n junction after the thermal diffusion step. FIG. 1 (part vi) shows a schematic of the diffused phosphorus dopants after the RTA process.

The annealing time is a critical process parameter that may directly influences the dopant diffusion depth and lateral extent, and consequently determines whether the resulting MOSFET operates in enhancement mode 180 or depletion mode 175, as will be discussed further in this technology. An annealing time in the range of approximately 1.5 to approximately 4 minutes at 950 °C may yield doping profiles suitable for enhancement-mode MOSFET 180 operation. Under these conditions, thermally diffusing the dopant atoms may produce a vertical dopant diffusion depth of about 100 nm to about 1 micrometer, for example approximately 500 nm into the silicon bulk, and a lateral dopant diffusion length of approximately 200 nm that does not bridge adjacent source and drain, or doped regions 170. Excessive annealing times (e.g., 6 to 8 minutes) may cause over-diffusion of phosphorus ions, which can bridge the channel region between the source and drain, or doped regions 170 to form a permanent n-channel, resulting in undesired depletion-mode behavior with significant drain current at zero gate voltage. Conversely, insufficient annealing time or temperature may not permit optimum doping and deteriorates device performance. Accordingly, precise control of the thermal budget during RTA is essential to achieving reliable MOSFET performance.

After the RTA diffusion step is complete, the spin-on-glass 130 encapsulation layer and any residual spin-on-dopant 125 composition may be removed from the semiconductor substrate 105. In an embodiment, the removal may be accomplished by wet etching the spin-on-glass 130 encapsulation layer and residual spin-on-dopant 125 composition with an aqueous hydrofluoric acid solution. In a specific embodiment, the aqueous hydrofluoric acid solution comprises about 5 vol. % hydrofluoric acid in water. Following the wet etch, the substrate 105 surface may be rinsed with deionized water and isopropanol (IPA) to ensure complete removal of etchant residue and any remaining contaminants. At this stage, the substrate 105 has precisely defined, highly localized doped regions 170 at the doping region 115 locations, ready for subsequent device completion steps such as gate dielectric deposition and contact metallization.

In an embodiment, the method further comprises, after removing the spin-on-glass 130 encapsulation layer and residual spin-on-dopant 125 composition on the surface, depositing one or more patterned structures 135 onto the pattern doped substrate 105 resulting from step H, thereby completing the field-effect transistor. Specifically, the cleaned substrate 105 with diffused dopant regions is patterned again using photolithography to define a gate dielectric region, as depicted in FIG. 1 (part vii). A gate dielectric layer 165, which may comprise aluminum oxide (Al₂O₃) having a thickness of approximately 50 nm, is then deposited via atomic layer deposition (ALD). Following dielectric deposition, source and drain contacts 155, a gate electrode 150, and other conductive structures 135 are formed by depositing a conductive metal stack, which may comprise titanium/gold (Ti/Au), at a thickness of approximately 150 nm, via electron beam evaporation, as depicted in FIG. 1 (part viii). The one or more patterned structures 135 may include one or more of a source structure 140, a drain structure, a gate dielectric, a gate electrode, an insulating layer, a metal contact, or an interconnect. The one or more device structures and the one or more doped regions 170 may form one or more metal-oxide-semiconductor field-effect transistors (MOSFETs), wherein the one or more device structures 135 are electrically coupled to the one or more doped regions 170.

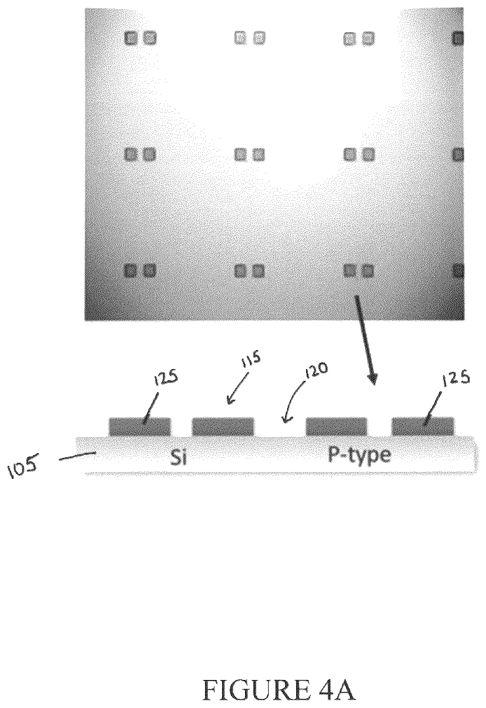

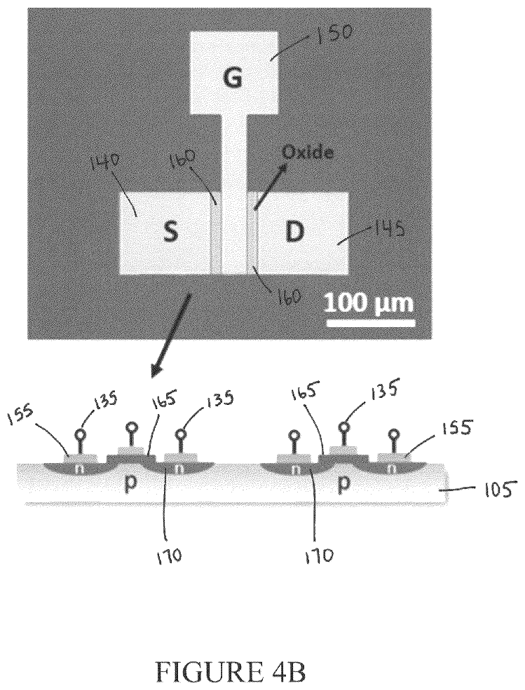

FIG. 4A and FIG. 4B show optical images from the MOSFET fabrication steps. As shown in FIG. 4A, the high selectivity of the functionalized silicon substrate 105 is readily observed, with SOD 125 deposited only at the source structure 140 and drain structure 145 designated locations, while ink dewetting occurs everywhere else because of the surface hydrophobicity. FIG. 4b shows optical images for the MOSFET after the final fabrication step.

The flexibility and reliability of this novel fluidic assembly fabrication process eliminates, except for the metal contacts, the need for using ion implantation, high-vacuum dopant deposition, and dry-etching techniques for the doping process as normally required by conventional fabrication processes in the semiconductor industry. In an embodiment, the method does not include use of ion implantation, high vacuum dopant deposition, or dry etching. The doping is instead achieved by a directed fluidic assembly process that can direct the SOD 125 to be printed only at the designated feature locations. Advantages of the present technology include the following. First, only one sacrificial layer is implemented (e.g., SOD 125), which reduces the number of steps needed to fabricate MOSFETs significantly, hence the overall time and fabrication cost can be minimized. Second, the technique paves the way to build fully additive electronic devices, without the need to implement surface-destructive techniques such as ion implantation, which also requires adding more annealing steps to re-heal the substrate 105 surface after implantation. Third, this approach is more flexible towards incorporating nanostructured materials, such as nanowires, nanopillars, and nanotubes, because aggressive dry etching and ion implantation can easily destroy these nanostructures. Fourth, the doping process is achieved through spin coaters and furnaces, making it cost-effective for labs, R&D, and small-volume production. Fifth, SOD 125 in general allows direct deep diffusion, in contrast to ion implantation, which usually creates shallow junctions, making this novel approach ideal for vertical device fabrication, such as MEMS actuators and high-voltage diodes.

Accordingly, the present technology also provides a semiconductor device comprising a semiconductor substrate 105, one or more doped regions 170 selectively formed in the semiconductor substrate 105 by thermal diffusion of dopant atoms from a spin-on-dopant 125 composition, and one or more device structures 135 electrically coupled to the one or more doped regions 170. The one or more doped regions 170 are selectively confined to designated locations on the substrate 105, such as source and drain regions, by the surface-energy-driven fluidic assembly and encapsulation process described herein. In one embodiment, the semiconductor device is a MOSFET having an on/off current ratio of at least about 10,000. In a further embodiment, the MOSFET has an effective mobility of at least about 250 cm²/V·s, or from about 300 cm²/V·s to about 320 cm²/V·s, as determined using field-effect transistor models.

The methods and devices of the present technology have broad applicability including, but not limited to, additive printed electronics, flexible electronics manufacturing, semiconductor device prototyping and research and development, low-power or energy-harvesting circuits, displays, solar cells, radio-frequency identification (RFID) devices, biochips for medical applications, and environmental monitoring electronic devices.

### Example 1. Device Fabrication and Characterization

The following example illustrates the fabrication and characterization of enhancement-mode MOSFETs 180 using the method of the present technology.

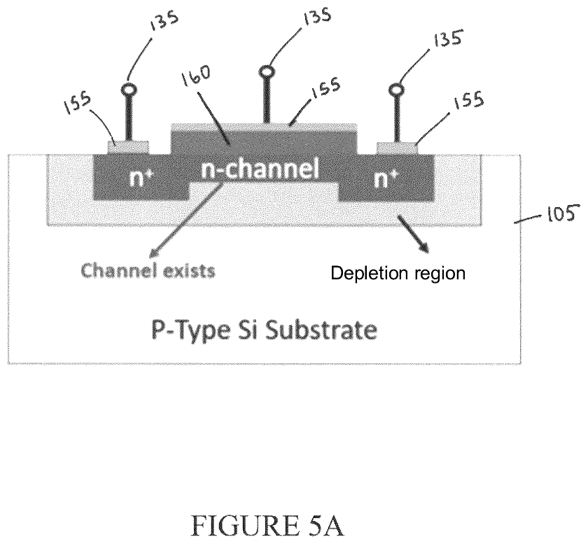

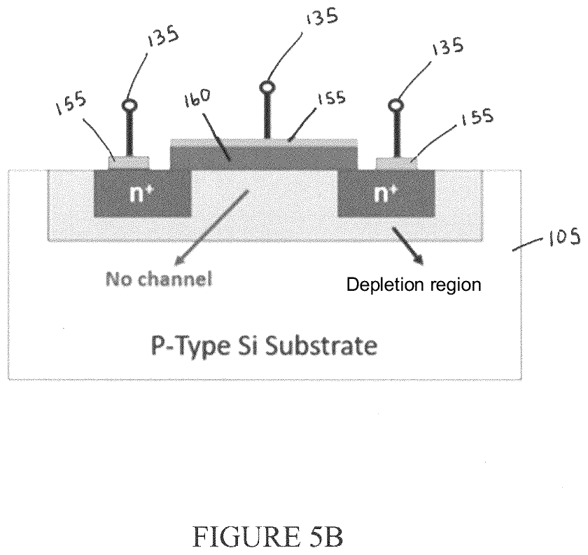

In general, MOSFET devices can operate in either depletion mode 175 or enhancement mode 180, as shown in FIGS. 5A and 5B. A depletion MOSFET 175, as depicted in FIG. 5A, has a permanent fabricated channel between the source and drain regions, whereas an enhancement MOSFET 180, as depicted in FIG. 5B, has no channel in between. In an enhancement-mode MOSFET 180, the source and drain doped regions 170 are laterally separated by a channel region that is not bridged by dopant atoms after the thermal diffusion step. The enhancement MOSFET 180 is normally OFF at zero gate voltage, while the depletion MOSFET 175 is normally ON at zero gate voltage because of the permanent fabricated channel. The enhancement MOSFET 180 has ultra-fast switching capability, making it preferred for use in electronic switching circuits, power electronics, inverter circuits, and amplifier circuits. Because of the desirability of ultra-fast switching applications, enhancement-mode MOSFET 180 operation is a preferred target of the present method, and the annealing parameters described above are selected to achieve enhancement-mode operation.

A boron-doped p-type silicon wafer having a (100) crystal orientation and a resistivity of 1-10 ohm·cm was cleaned sequentially with acetone, deionized water, and isopropanol, and dried under a nitrogen stream. Photolithography was used to define source regions and drain regions on the wafer. The wafer was then subjected to oxygen plasma treatment to remove organic residues and render the exposed source regions and drain regions hydrophilic. The substrate 105 was subsequently exposed to 2H-perfluorododecyltrichlorosilane (PETS) vapor at 95 °C for 3 minutes, forming an approximately 3 nm thick self-assembled monolayer on the exposed regions. After photoresist 110 removal, a chemically heterogeneous surface was obtained with hydrophilic source structure 140 and drain structure 145 (water contact angle ~0°) surrounded by a hydrophobic background (water contact angle ~110°).

The chemically modified silicon substrate 105 was immersed in spin-on-dopant 125 phosphorus ink (PDC5-2500) and withdrawn at 40 mm/min. Because of the heterogeneous nature of the silicon substrate 105 surface, the ink preferentially assembled at the hydrophilic source regions and drain regions, while the ink de-wetted from the hydrophobic regions. After assembly, the substrate 105 was soft baked at 150 °C for 5 minutes to remove organic solvents. A 300 nm spin-on-glass 130 layer (IC1-1000) was deposited via spin coating on top of the printed SOD 125, and the substrate 105 was annealed at 200 °C for 10 minutes to remove organic solvents from the SOG 130 layer. The substrate 105 was then annealed using rapid thermal annealing at 950 °C to diffuse the phosphorus dopants into the silicon substrate 105. Following diffusion, the SOD 125 layer was wet etched using hydrofluoric acid (HF, 5 vol. % in H₂O) and then the surface was rinsed with deionized water and IPA.

The cleaned substrate 105 with diffused phosphorus was patterned again using photolithography to deposit a 50 nm aluminum oxide (Al₂O₃) gate dielectric via atomic layer deposition (ALD). Source, drain, and gate Ti/Au contacts 155 (150 nm) were deposited using electron beam evaporation to finalize the fabrication process.

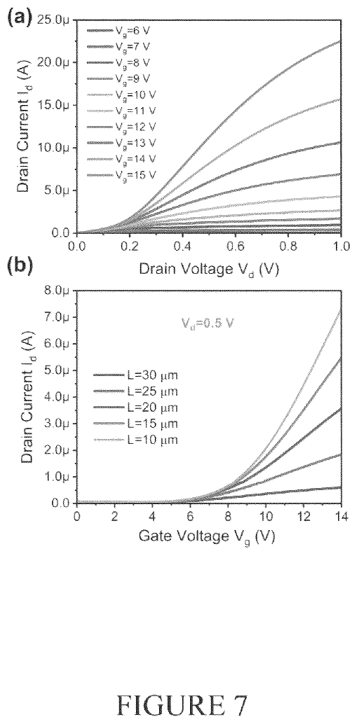

The fabricated MOSFETs exhibited excellent electrical performance. Devices fabricated with a channel length of 10 μm and a channel width of 100 μm demonstrated effective mobilities (μeff) of approximately 320 cm²/V·s in the linear regime and approximately 300 cm²/V·s in the saturation regime, with an effective mobility of at least about 250 cm²/V·s, as determined using dark-field-effect transistor models. The drain current was negligible at zero gate voltage, confirming enhancement-mode operation, as shown in FIG. 7A. Transfer characteristic measurements at Vd=0.5 V across channel lengths of 10, 15, 20, 25, and 30 μm, as shown in FIG. 7B, revealed that the best transfer characteristics occurred at a 10 μm channel length, with an on/off current ratio of at least about 10⁴.

As the length of the channel increases, the resistance of the channel proportionally increases. This is attributed to the fixed annealing time applied for phosphorus ions to diffuse, which makes the diffusion distance of phosphorus inside the silicon substrate 105 equal in all cases. By increasing the channel length, a larger gate voltage is needed to induce more charge along the channel. On the other hand, at smaller channel lengths (e.g., 5 μm), control of the annealing process becomes challenging, and the channels may exhibit high drain current at zero gate voltage, indicating that the phosphorus dopant has diffused and bridged the channel region between the source regions and drain regions to form a depletion-mode MOSFET 175.

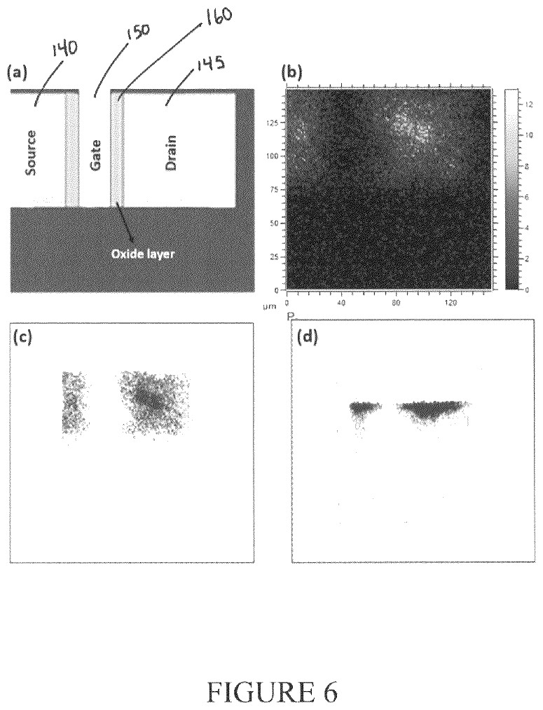

In order to investigate the phosphorus doping distribution inside the silicon substrate 105 for the fabricated MOSFETs, time-of-flight secondary ion mass spectroscopy (TOF-SIMS) was conducted. FIG. 6A shows an optical image for the region selected for the measurements. FIG. 6B shows a normalized distribution for the phosphorus ions over the selected region. TOF-SIMS analysis shows dopant atoms selectively located underneath the source and drain contacts 155, without forming a continuous doped channel between the source and drain contacts 155. This is attributed to the SOG 130 encapsulation layer employed during the fabrication process. FIG. 6C and FIG. 6D show the planar and in-depth phosphorus distribution across the silicon substrate 105, respectively. The results reveal that the phosphorus diffusion under the optimized annealing conditions did not extend between the source regions and drain regions underneath the gate contact, confirming that the fabricated devices operate in the enhancement mode as desired.

### Example 2. Device Modeling and Optimization

The doping process may be further optimized through computer-aided design (CAD) modeling and simulation. In an embodiment, a CAD tool such as the Silvaco software package is used to model the fabrication process and simulate device electrical behavior. The Silvaco package includes an “Athena” module, which is used to simulate fabrication steps including implantation and diffusion, and an “Atlas” module, which is employed to simulate the device electrical behavior by applying bias to the modeled structure and extracting electrical characteristics such as current-voltage (I-V) curves. These simulations facilitate the investigation of annealing conditions on the doping profile and allow optimization of the thermal budget to achieve the desired MOSFET operating mode.

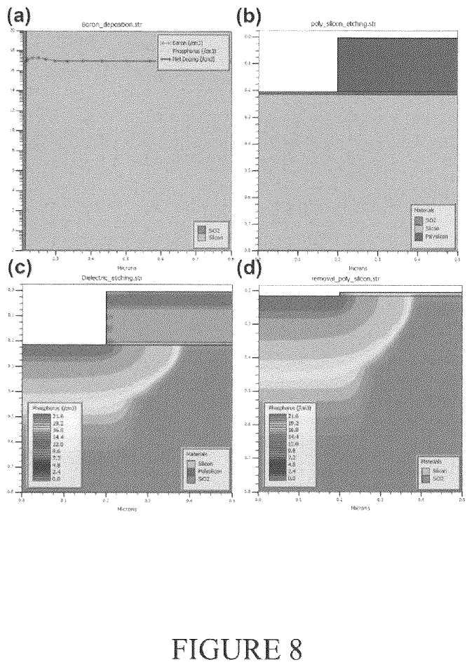

As shown in FIG. 8, the simulation begins by creating a p-doped silicon substrate 105 using boron ion implantation at a concentration of approximately 8×10¹² ions/cm² with an implantation energy of approximately 100 keV, followed by a thermal diffusion step at approximately 950 °C for approximately 100 minutes under oxygen and HCl flow. FIG. 8A shows the resulting boron and phosphorus doping profiles across the silicon substrate 105, confirming that the net charge is equivalent to the boron concentration, indicating a p-type doped silicon substrate 105. After doping the substrate 105, an oxide layer is deposited on top to serve as a gate dielectric layer. The diffusion of the oxide layer is performed at approximately 925 °C for approximately 11 minutes under a dry oxygen atmosphere and HCl flow, producing an oxide layer of approximately 25 nm thickness, which is equivalent to the oxide layer thickness fabricated experimentally. An additional boron implantation step is then performed to readjust the p-type concentration profile at the interface after the gate oxide layer formation.

Following formation of the p-type substrate 105, the area underneath the gate is protected before phosphorus implantation by depositing a sacrificial layer of polysilicon on top of the designated gate region, as shown in FIG. 8B. This simulation step is equivalent to the experimental step in which the substrate 105 is coated with a spin-on-glass 130 (SOG) layer to encapsulate the spin-on-dopant 125 and to control its diffusion to the designated source regions drain regions only. The thickness of the deposited polysilicon layer in the simulation is approximately 200 nm, equivalent to the SOG 130 thickness used experimentally. After protecting the gate region, phosphorus ion implantation is performed at a concentration of approximately 3×10¹³ ions/cm² with an implantation energy of approximately 20 keV, which was found to produce a diffusion profile similar to the experimental SOD 125 thermal diffusion. As shown in FIG. 8C, the phosphorus ions are then diffused at approximately 950 °C for approximately 4 minutes under nitrogen gas at atmospheric pressure. The phosphorus concentration is higher at the silicon surface, where the diffusion starts, then decreases gradually with depth until reaching the original concentration (approximately 1×10¹⁴ ions/cm³) deep in the silicon bulk. Based on the simulation, after annealing at 950 °C for 4 minutes, the phosphorus ions exhibited a vertical diffusion length of approximately 500 nm inside the silicon bulk and a lateral diffusion length of approximately 200 nm. After phosphorus diffusion, the masking polysilicon layer is etched, as shown in FIG. 8D, which is equivalent to the SOG 130 experimental masking layer etching depicted in FIG. 1 (part vi).

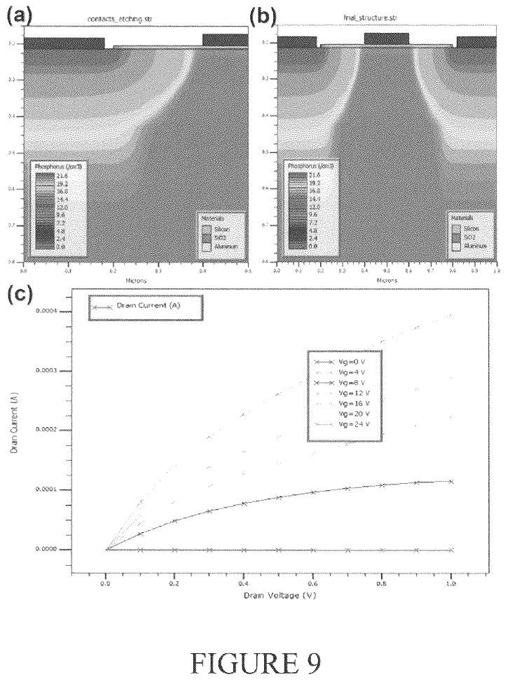

After the phosphorus diffusion step, aluminum contacts of approximately 300 nm thickness are deposited on the silicon substrate 105, as shown in FIG. 9A. The structure is then mirrored around its axis to achieve the final MOSFET structure, as shown in FIG. 9B. As can be observed, the diffusion temperature and time are optimized so that phosphorus ions do not diffuse long enough to bridge the channel underneath the gate between the source contacts 155 and drain contacts, thereby ensuring normal operation of the MOSFET in enhancement mode 180, where the channel layer is created solely by the applied gate voltage. After depositing the contacts and finalizing the fabrication process in the simulation, the I-V characteristic curve for the modeled structure is calculated using the “Atlas” module of the Silvaco package. As shown in FIG. 9C, the drain voltage (Vd) is swept between 0-1 V with gate voltage increasing from 0-24 V in 4 V increments. The output curve resulting from the simulation is similar to the I-V characteristic curve achieved experimentally, with negligible drain current at zero gate voltage, confirming that the simulated transistor operates in enhancement mode 180 consistent with the experimental observations.

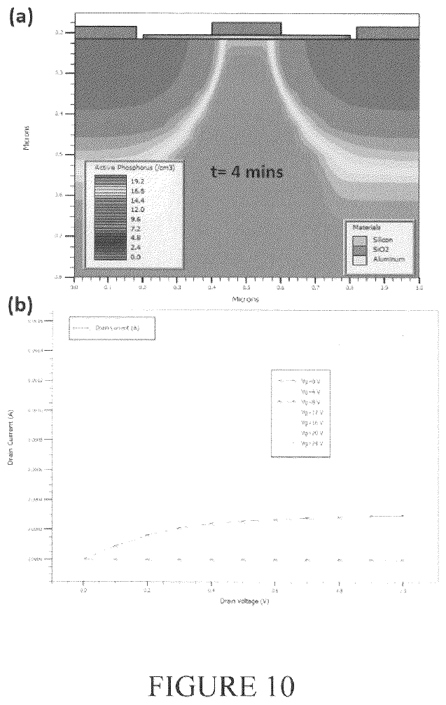

In order to investigate the effect of annealing time on phosphorus ion diffusion inside the silicon substrate 105, the “Athena” module was used to build different MOSFET models with different annealing times of approximately 4 minutes, approximately 6 minutes, and approximately 8 minutes at 950 °C, with all other design parameters held constant so that device performance is a function of annealing time only. For each annealing time, the I-V characteristics were extracted to investigate device performance using the “Atlas” module. As shown in FIG. 10A, at an annealing time of approximately 4 minutes, the phosphorus ions diffuse into the silicon substrate 105 with an optimum depth profile sufficient to create an n-channel region only when a positive gate voltage is applied, yielding enhancement-mode MOSFET 180 operation. This is confirmed by the I-V characteristics curve shown in FIG. 10B, where there is no drain current passed through the device at zero gate voltage, which is typical behavior for an enhancement-mode MOSFET 180. These simulation results are consistent with the experimental findings described above. Under these simulation conditions, the phosphorus ions exhibited a vertical diffusion length of approximately 500 nm inside the silicon bulk and a lateral diffusion length of approximately 200 nm, consistent with the experimental results.

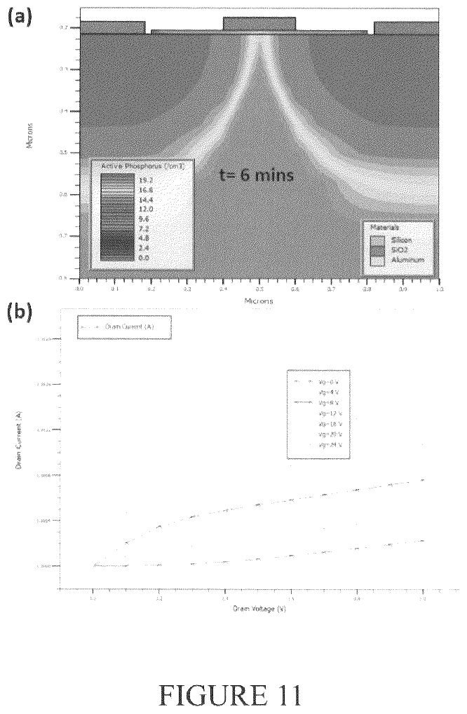

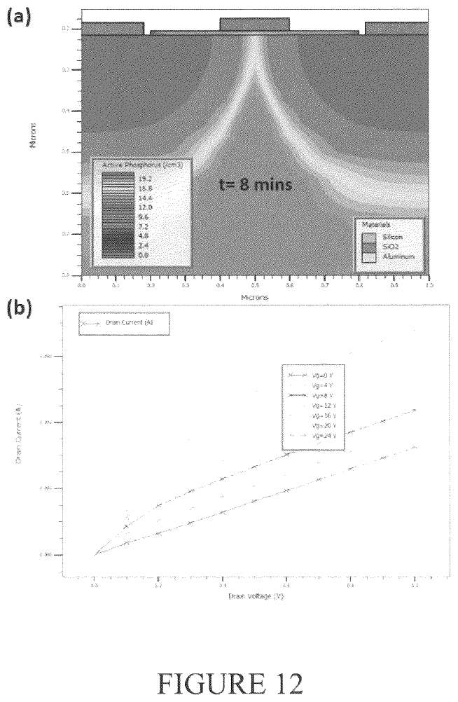

At increased annealing times, such as approximately 6 minutes, the simulation showed that the phosphorus ions had sufficient time to diffuse and significantly reduce the channel length under the gate, as shown in FIG. 11A. This resulted in a small drain current flow at zero gate voltage, as can be observed in FIG. 11B. By further increasing the annealing time to approximately 8 minutes, the phosphorus ions completely diffused under the gate and formed a permanent n-channel, as shown in FIG. 12A, resulting in large drain current flow at zero gate voltage and depletion-mode MOSFET 175 behavior, as shown in FIG. 12B. These simulation results are consistent with the experimental findings and further confirm the critical role of annealing time in achieving optimum enhancement-mode MOSFET 180 performance.

As used herein, “consisting essentially of” allows the inclusion of materials or steps that do not materially affect the basic and novel characteristics of the claim. Any recitation herein of the term “comprising”, particularly in a listing of components of a composition or elements of a device, constitutes inclusion of alternative embodiments in which “comprising” is replaced with “consisting essentially of” or “consisting of”.

While the present invention has been described in conjunction with certain preferred embodiments, one of ordinary skill, after reading the foregoing specification, will be able to effect various changes, substitutions of equivalents, and other alterations to the compositions and methods set forth herein.

1. A method of patterned doping of a substrate, the method comprising:
(a) providing a semiconductor substrate having a hydrophilic surface;
(b) applying a patterned photoresist coating to the substrate surface using lithography, thereby covering one or more selected doping regions and exposing one or more non-doping regions on the surface;
(c) forming a hydrophobic self-assembled monolayer on the one or more exposed non-doping regions thereby rendering them hydrophobic;
(d) removing the patterned photoresist coating while leaving the self-assembled monolayer on the one or more non-doping regions, thereby exposing the substrate surface in the one or more selected doping regions;
(e) depositing a spin-on-dopant on the exposed substrate surface in the one or more doping regions using fluidic assembly, whereby the spin-on dopant composition selectively wets and coats the one or more selected doping regions and de-wets from the one or more non-doping regions;
(f) depositing a spin-on-glass encapsulation layer over the entire surface of the semiconductor substrate resulting from step (e), whereby the one or more doping regions and the one or more non-doping regions are covered by the encapsulation layer;
(g) thermally diffusing dopant atoms from the spin-on-dopant composition into the semiconductor substrate selectively in the one or more intended doping regions while the spin-on-glass encapsulation layer confines the spin-on-dopant composition to the one or more doping regions; and
(h) removing the spin-on-glass encapsulation layer and residual spin-on-dopant from the semiconductor substrate.

2. The method of claim 1, further comprising, prior to B, treating the substrate with an oxygen plasma, whereby a surface of the substrate becomes hydrophilic.

3. The method of claim 1, wherein step C comprises exposing the substrate surface to perfluorooctyltrichlorosilane (FOTS) vapor, or another fluorinated organosilane to form the self-assembled monolayer.

4. The method of claim 3, wherein the self-assembled monolayer has a thickness of about 3 nanometers and a contact angle of about 110 degrees.

5. The method of claim 1, wherein the depositing in step E comprises dip coating, fast fluidic assembly, or directed fluidic assembly by immersing the semiconductor substrate in a spin-on-dopant solution and withdrawing the substrate through a surface of the solution.

6. The method of claim 5, wherein the semiconductor substrate is withdrawn at a speed from about 10 mm/min to about 100 mm/min, preferably about 40 mm/min.

7. The method of claim 1, further comprising, after selectively depositing the spin-on-dopant composition, heating the spin-on-dopant composition at a temperature from about 100 °C to about 200 °C for a time sufficient to remove at least a portion of solvent from the spin-on-dopant composition before depositing the spin-on-glass encapsulation layer.

8. The method of claim 1, further comprising heating the spin-on-glass encapsulation layer at a temperature from about 150 °C to about 250 °C for a time sufficient to remove at least a portion of solvent from the spin-on-glass encapsulation layer before thermally diffusing the dopant atoms.

9. The method of claim 1, wherein thermally diffusing the dopant atoms comprises rapid thermal annealing at a temperature from about 850 °C to about 1050 °C for a duration from about 30 seconds to about 2 minutes under an inert atmosphere.

10. The method of claim 1, wherein step (h) comprises wet etching the spin-on-glass encapsulation layer and residual spin-on-dopant composition with an aqueous hydrofluoric acid solution.

11. The method of claim 1, wherein the spin-on-dopant comprises a source of n-type dopant or a source of p-type dopant.

12. The method of claim 1, wherein the spin-on-dopant comprises phosphorus atoms or boron atoms, or a compound comprising phosphorus or boron.

13. The method of claim 1, wherein the semiconductor substrate comprises a semiconductor material having a first conductivity type, and wherein the spin-on-dopant composition provides dopant atoms of a second, opposite conductivity type in the one or more selected doping regions, such that an interface between a doped region and an adjacent non-doped or differently doped region forms a p-n junction after the thermal diffusion step.

14. The method of claim 1, wherein the semiconductor substrate comprises or consists of silicon, silicon carbide, germanium, gallium nitride, gallium arsenide, or any combination thereof.

15. The method of claim 1, further comprising, after removing the spin-on-glass encapsulation layer and residual spin-on-dopant composition on the surface, depositing one or more patterned structures onto the pattern doped substrate resulting from step H.

16. The method of claim 15, wherein the one or more patterned structures are one or more of a source contact, a drain contact, a gate dielectric, a gate electrode, an insulating layer, a metal contact, or an interconnect.

17. The method of claim 15, wherein the one or more device structures and the one or more doped regions form one or more metal oxide semiconductor field effect transistors (MOSFETs).

18. The method of claim 17, wherein the one or more MOSFETs are enhancement-mode MOSFETs in which source and drain doped regions are laterally separated by a channel region that is not bridged by dopant atoms after the thermal diffusion step.

19. The method of claim 1, wherein the method does not include use of ion implantation, high vacuum dopant deposition, or dry etching.

20. The method of claim 1, wherein the one or more doping regions have a lateral dimension in a range from about 1 micrometer to about 1 centimeter.

21. The method of claim 1, wherein thermally diffusing the dopant atoms produces a vertical dopant diffusion depth of about 100 nm to about 1 micrometer and a lateral dopant diffusion length that does not bridge adjacent source and drain regions.

22. A semiconductor device comprising a semiconductor substrate, one or more doped regions selectively formed in the semiconductor substrate by thermal diffusion of dopant atoms from a spin-on-dopant composition, and one or more device structures electrically coupled to the one or more doped regions.

23. The semiconductor device of claim 22 which is a MOSFET having an on/off current ratio of at least 10000.

24. The semiconductor device of claim 23, wherein the MOSFET has an effective mobility of at least about 250 cm²/V·s, or about 300 cm²/V·s to about 320 cm²/V·s.
